(19) United States
(12) Patent Application Publication
(10) Pub. No.: US 2005/0121807 A1
(43) Pub. Date: Jun. 9, 2005

(54) Arrangement of a chip package constructed on a substrate and substrate for production of the same

(76) Inventors: Martin Reiss, Ottendorf-Okrilla OT Medingen (DE); Stephan Blaszczak, Freyburg (DE); Bernd Scheibe, Dresden (DE); Kerstin Nocke, Dresden (DE); Carsten Bender, Dresden (DE)

Correspondence Address: SLATER & MATSIL LLP, 17950 PRESTON ROAD, SUITE 1000, DALLAS, TX, 75252, US

(21) Appl. No.: 10/961,820

(22) Filed: Oct. 8, 2004

(30) Foreign Application Priority Data
Oct. 8, 2003 (DE) 103 47 320.3

(51) Int. Cl. H01L 23/48

(52) U.S. Cl. 257/787

(57) ABSTRACT

A packaged chip includes a substrate that includes flat and rigid supporting regions that are connected to an upper surface of the substrate. A chip is mounted face-down on the upper surface of the substrate such that a connection between the substrate and the chip extends virtually completely over one side of the chip. An encapsulating compound overlies a backside of the chip. Further, rigid supporting zones can be connected to the backside of the chip such that the supporting zones are at least partly interconnected with the encapsulating compound.

This application claims priority to German Patent Application No. 103 47 320.3, which was filed Oct. 8, 2003, and is incorporated herein by reference.

### TECHNICAL FIELD

The invention relates to a substrate for the production of a chip package constructed on this substrate, and also to an arrangement of such a chip package constructed on a substrate.

### BACKGROUND

Substrate-based packages are known in various forms, such as for example the Board-on-Chip devices (BOC or else COB devices), the Chip Size Packages (CSP devices), the FBGA (Fine Pitch Ball Grid Array) devices, the TBGA (Tape Ball Grid Array) devices or the μBGA devices. In the case of these devices, chips are predominantly mounted with the active side downwards (face-down) on substrates, which are only slightly larger than the chips themselves. The various types differ in particular in the envisaged integration into a circuit system and in different degrees of structural fineness.

To protect the package and for better handling during further processing, the chip is surrounded completely (backside protection) or at least peripherally on its side faces (edge protection) with an encapsulating compound (molding compound), which can be applied by various methods, dispensing, molding or printing. This establishes a firm connection between the encapsulating compound and the chip and also between the encapsulating compound and the substrate, with the result that the chip and substrate are also mechanically connected by means of the encapsulating compound.

On account of the materials joined in this way, of the substrate (synthetic resin) and of the chip (silicon), which have different expansion characteristics, the package shows warping characteristics comparable to a bimetallic effect, in particular under thermal loading, as occurs for example during alternating temperature tests and burn-in (artificial pre-aging). The warping characteristics lead to stress moments in the mechanical and electrical contacting pads on the one hand between the chip and the substrate and on the other hand also between the substrate and a module, such as for example a PCB (Printed Circuit Board) into which the package is integrated, and consequently lead to reliability problems on the substrate side and in particular considerable reliability problems on the module side, which may lead to the total failure of the device.

While the reliability problems on the substrate side can be reduced primarily by suitable stress-absorbing adhesive connections, for example tapes, the reliability problems on the module side have been counteracted, with varying results, by the arrangement of the electrical contacts between the substrate and the module being adapted to correspond to the distribution of failed contacts established under defined thermal and mechanical loading. A specific pad design is also only successful to a limited extent and for selected cases.

Another variant for improving the reliability of electrical contacts both on the module side and on the substrate side is to choose the encapsulating compound such that it is capable of absorbing the stresses produced by the warping characteristics and consequently of relieving the electrical contacts. This has been achieved by the use of highly flexible encapsulating compounds, but had the disadvantage of a deterioration in the wetting capability, and consequently the reliability of the mechanical connection between the encapsulating compound and the substrate.

The possibilities described in any case only represent the adaptation of the electrical and/or mechanical contacting pads to the warping characteristics of the materials involved and can only ever take place quite specifically for certain packages under defined conditions. The causes of the reliability problems, the warping characteristics themselves, are not influenced however by these measures, as a result of which these measures can only lead to limited success.

A limited reduction of the warpage has been brought about by modifications of the material combinations within the package. However, this is only possible within the limits allowed by the still existing material pairings. Not only the materials of the chip and of the encapsulating compound that are in contact with one another but also the materials of the encapsulating compound and of the substrate and, not least, further combinations which exist as a result of a layered construction of the substrate itself nevertheless have clear differences in the coefficients of thermal expansion and consequently warping of the package.

Apart from the reliability problems discussed, the warping characteristics also lead to production problems, in particular in the loading of substrate strips with a number of chips arranged next to one another, known as the matrix strips. Depending on the chip sizes and the process conditions, the matrix strips sometimes show in the course of production bowing values, which hinder or even prevent dependable processability.

In this case, too, so far the warping characteristics themselves have not been reduced, but instead the problem has been avoided by selective exploitation or extension of the specifications of the process installations or by the use of mechanical aids, such as for example holders for pressing back the bowing.

### SUMMARY OF THE INVENTION

Consequently, aspects of the invention provides means with the aid of which the warping characteristics of substrate-based packages can be selectively influenced both in the mounted state and already during the production process and which can at the same time be produced at low cost and with the existing installations and processes.

For example, on the one hand flat and rigid supporting regions which are connected to the surface of the substrate and partially cover the substrate can be arranged at least on one side of the substrate.

Because of their strength, and mainly because of the partial coverage, these supporting regions perform a stiffening function on the substrate and via the latter on the package as a whole. Since the supporting regions do not take up the entire surface area of the substrate, the disparity in the expansion characteristics of these two connected, different types of materials, such as that which occurs in the known packages, does not arise between the substrate and the supporting regions. The expansion characteristics of the supporting regions adapt themselves to the greatest extent to those of the substrate. In the direction of its principal extent, however, each supporting region stiffens the substrate, against the tensile forces of the silicon, which expands much less than the substrate, of a chip mounted on the substrate. In this way, the form of each individual supporting region, and in particular the spacing and number of the supporting regions following one another in a specific direction, determine the warping characteristics of the substrate.

The flat configuration, in the sense of a small thickness comparable to that of a layer of adhesive, has the effect that the supporting regions fit in with the construction of each package, in that they are located in a plane preferred for the respective package construction between the substrate surface and the connecting plane with respect to the chip or else the module, as long as there is sufficient space to allow a specific direction of extent, and consequently direction of stiffening, to be realized. Otherwise, however, this flat configuration also allows the arrangement of wiring levels above or below the level of the supporting regions, to produce the space required for the structures of the supporting regions. The plane in which the supporting regions are ultimately arranged can be freely determined in accordance with the arrangement of the contact pads and the construction of the package.

The advantages described of a stiffening structure of supporting regions are not restricted however to individual substrates of individual packages, but can also be applied to intermediate products of the package production, in particular matrix strips before their further coating or component loading, whereby their warping characteristics in thermal process steps of the production can also be reduced, and in this way the production problems described can be reduced or even prevented.

If, in accordance with particularly advantageous embodiments, the supporting regions are created by a lacquer layer or even in the solder stop mask, production with the existing installations and processes is possible and, in particular with appropriate structuring of the solder stop mask, does not require any further process steps. In this case, exploitation is made of the fact that the solder stop mask that is present in the package underneath and above the substrate is involved in a significant way in the thermal movements of the package and is influenced in the desired way by a selective structuring, creating the supporting regions according to the invention.

In the same way as by empirical investigations, with knowledge of the thermomechanical properties of the materials involved and the thermal sequences during production, testing or burn-in, it is possible in particular to determine the warping characteristics of the package exactly by thermomechanical simulations, with the result that, in another advantageous refinement of the invention, the distribution of the supporting regions on the substrate can be fixed with regard to their position and size in such a way that their geometry corresponds to the areal distribution and the extent of the warping of the substrate generated under process and operating conditions. As a result, the supporting regions are arranged exactly at such locations and in such a manner that they specifically counteract the warping characteristics determined and transfer their influence optimally to the package as a whole.

Another solution provided by the invention likewise relies on the stiffening effect of a modified existing element of the package, provides that rigid supporting zones that are connected to the backside and partially cover it are arranged directly on the backside of the chip and the supporting zones are at least partly interconnected with the encapsulating compound of the backside and/or edge protection.

Because of their partial coverage and their rigidity, these supporting zones, comparable with the supporting regions present on the substrate, exert the same mechanical, stiffening effect as the supporting zones directly on the substrate, but in this arrangement on a chip mounted on the substrate. The discretely arranged supporting zones are also capable of adapting themselves to the expansion characteristics of the chip.

In order to enhance the stiffening effect of the supporting zones present in the uppermost level of the package arrangement and transfer it to the package as a whole, they are at least partly interconnected with the insulating compound.

To be regarded as a further advantage of the supporting zones, as a result of the position in one of the uppermost levels of the package arrangement, they do not necessarily have to be constructed as a layer. If, however, the possible height of the package is limited, a flat construction, with a thickness, which is comparable with that of a layer of adhesive, is possible with a comparable effect.

In a particularly advantageous refinement of the invention, the supporting zones are formed by a curable compound with less flexibility in comparison with the encapsulating compound. As a result of the selective, at least partial connection of a material that is comparable with the encapsulating compound, but less flexible, with the more flexible, stress-compensating encapsulating compound itself, it is possible to adapt the properties of the backside and/or edge protection optimally to the respective chip size and the necessary thermomechanical properties of the package that are also determined as a result.

In the same way as the supporting regions, the supporting zones are also suitable for positively influencing the warping characteristics of intermediate products, and here in particular of matrix strips in which a series of chips are mounted. In this case, the structures of the supporting zones are applied from a curable material before the encapsulation of each individual chip backside. In addition, the variable placement of particularly optimized encapsulating compounds in the vicinity of particularly stressed electrical contacts makes further advantages possible in the influencing of the warping characteristics.

On account of the material used, the application of the supporting zones finds its place in the customary production process and in particular is possible by the known, tried-and-tested methods of molding, printing and dispensing.

As already discussed in the description of special embodiments of the supporting regions according to the invention, it is possible in a refinement of the supporting zones according to the invention that they are distributed on the chip backside with regard to their position and size in such a way that their geometry corresponds to the areal distribution and the extent of the warping of the chip generated under process and operating conditions. In this case, the warping characteristics of the mounted package are determined on a detailed basis by empirical investigations, or preferably by thermomechanical simulation, and the supporting zones are accordingly arranged in an optimizing manner.

The extent of the stiffening effect and its direction can be determined in advance in particular if, according to further refinements according to the invention, the areal form of the supporting zones corresponds to basic geometrical forms. This can be appreciated in particular in cases where the supporting zones are supporting strips.

If, for example, a number of supporting strips are arranged in parallel, they counteract the warping in this one direction to a particularly great extent. If, on the other hand, at least one supporting strip is arranged transversely in relation to at least one further supporting strip, the influencing of the warping characteristics takes place in the two directions defined by the supporting strips.

A further particularly advantageous configuration according to the invention provides that, in addition to the supporting zones on the chip backside of the chip mounted face-down on the substrate, on the substrate there are arranged flat and rigid supporting regions, which are connected at least on one side to the surface of the substrate and partially cover the substrate.

This combines the described advantages of the supporting zones with those of the supporting regions and multiplies the possibilities of influencing the warping characteristics of the package or of intermediate products in the production process. Apart from the various embodiments of the supporting zones, those of the supporting regions are now additionally available, making it possible for even more selective influence to be exerted.

Therefore, a great increase in the effect can be achieved if the supporting zones on the chip backside and the supporting regions on the substrate are arranged identically and an effect which is uniform over the entire extent can be achieved if the supporting zones on the chip backside and the supporting regions on the substrate are arranged such that they are essentially offset and/or turned by 90° in relation to one another.

### BRIEF DESCRIPTION OF THE DRAWINGS

The invention is to be explained in more detail below on the basis of an exemplary embodiment. In the associated drawing:

FIG. 1 shows an enlarged extract from a schematic sectional representation of a package according to the invention;

FIG. 2a and 2b (collectively referred to as FIG. 2) show the schematic representation of two substrates according to the invention in plan view; and

FIG. 3a and 3b (collectively referred to as FIG. 3) show the schematic representation of horizontal sections of two arrangements according to the invention, taken at the level of the chips backsides.

The following list of reference symbols can be used in conjunction with the figures:
1 substrate
2 tape
3 chip
4 bonding channel
5 metallization
6 contact pad
7 bonding pad
8 central contacts
9 wire bridges
10 solder ball
11 encapsulation
12 first solder stop mask
13 second solder stop mask
14 openings
15 lands
16 supporting regions
17 supporting zones
18 encapsulating compound
19 base

### DETAILED DESCRIPTION OF ILLUSTRATIVE EMBODIMENTS

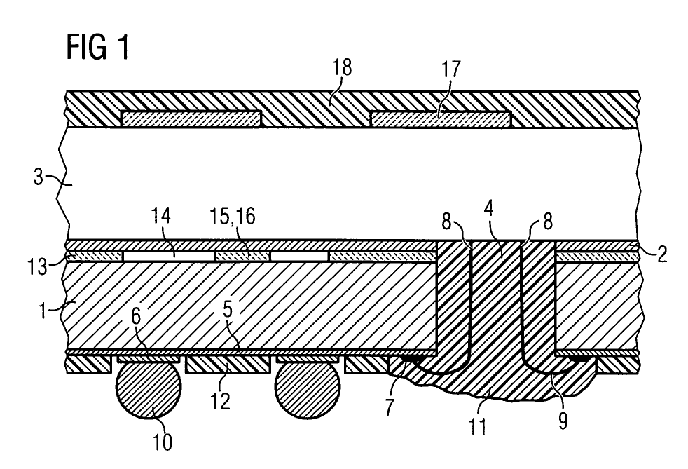

The sectional representation in FIG. 1 shows a substrate 1, on which a chip 3 is adhesively attached face-down by means of a tape 2. The substrate 1 has a passage, the bonding channel 4, and on the underside a patterned metallization 5. The metallization 5 comprises contact pads 6 arranged in the manner of a grid and bonding pads 7 present in the edge region of the bonding channel 4, and electrically connects them to one another. The double-rowed central contacts 8 of the chip 3 are contacted through the bonding channel 4 by means of wire bridges 9 on the bonding pads 7 and the package is contacted by means of the solder balls 10 present on the contact pads 6 on a module that is not represented. The bonding channel 4 including the wire bridges 9 and the bonding pads 7 is sealed by an encapsulation 11.

To protect the underside metallization 5 and limit the solder flow during the soldering process for mounting the package on the module that is not represented, the metallization 5 is covered by a first solder stop mask 12, leaving the contact pads 6 and the bonding channel 4 free.

Applied directly to the upper surface of the substrate 1 is a second solder stop mask 13, which is patterned in such a way that, on the one hand it leaves the bonding channel 4 open and on the other hand it has further openings 14 in such a way that lands 15 of various width remain between them. These lands 15 form the supporting regions 16 according to the preferred embodiment of the invention.

Applied from an epoxy resin compound to the upward-facing rear side of the chip 3, in the present exemplary embodiment preferably by printing, over certain portions are flat supporting zones 17, the flexibility of which is less than that of the resin compound 18 applied to the chip 3 as backside protection and enclosing the supporting zones 17 on their free sides.

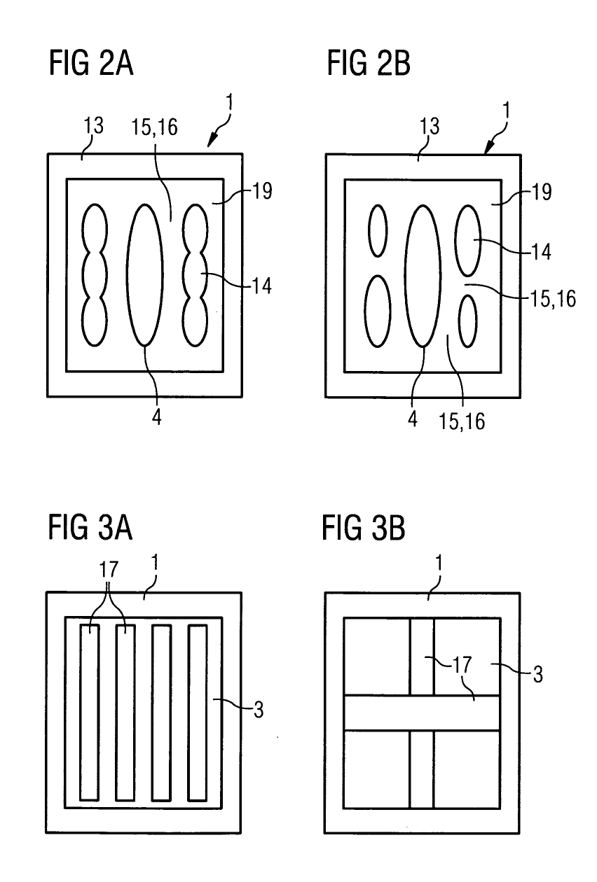

Neither an alignment of the supporting regions 16 nor an alignment of the supporting zones 17 is evident in the sectional representation. Some possible alignments of the supporting regions 16 are represented in FIG. 2 and some possible alignments of the supporting zones 17 are represented in FIG. 3.

The two substrates 1 in FIGS. 2a and 2b are covered over their full surface area by the second solder stop mask 13. The central, rectangular region, as the base 19, represents the region, which is later covered by the chip 3 after it has been mounted on the substrate 1. The second solder stop mask 13 has in FIG. 2a next to the open bonding channel 4 a number of merging openings 14, between which there are the lands 15, which form the supporting regions 16 according to the invention. In this exemplary embodiment, apart from a frame running around in the base 19, the lands 15 predominantly run in one direction, with the result that the stiffening effect principally occurs in this direction.

The openings 14 in the second solder stop mask 13 in FIG. 2b, on the other hand, are discrete, with the result that there are also smaller lands 15, running at right angles in relation to the lands 15 running parallel to the bonding channel 4, and consequently a stiffening effect is also to be noted in this direction.

FIG. 3 shows the backsides of two chips 3, which are mounted face-down on a slightly larger substrate 1 in each case. Arranged on the backside of the chip 3 in FIG. 3a are parallel supporting zones 17 in the form of strips, which leave a small edge region free on the backside of the chip 3, so that the main direction of effect is in the direction of the supporting zones 17, comparable to FIG. 2a.

On the other hand, the mutually perpendicular supporting zones 17 in the form of strips in FIG. 3b bring about a stiffening of the chips 3 in both these directions.

1. A packaged chip comprising:
a substrate that includes flat and rigid supporting regions that are connected to an upper surface of the substrate and partially cover the substrate;
a chip mounted face-down on the upper surface of the substrate, such that a connection between the substrate and the chip extends virtually completely over one side of the chip; and
an encapsulating compound overlying a backside of the chip.

2. The packaged chip of claim 1, and further comprising rigid supporting zones connected to the backside of the chip such that the supporting zones are at least partly interconnected with the encapsulating compound.

3. The packaged chip of claim 1, wherein the supporting regions are formed by a lacquer layer.

4. The packaged chip of claim 1, wherein the supporting regions are formed in a solder stop mask.

5. The packaged chip of claim 1, wherein the supporting regions are distributed on the substrate with regard to their position and size in such a way that their geometry corresponds to an areal distribution and the extent of the warping of the substrate generated under process and operating conditions.

6. A packaged chip comprising:
a substrate;
a chip mounted face-down on the substrate;
an encapsulating compound overlying a backside of the chip; and
rigid supporting zones connected to the backside of the chip, the supporting zones at least partly interconnected with the encapsulating compound.

7. The packaged chip of claim 6, wherein the encapsulating compound further overlies edges of the chip.

8. The packaged chip of claim 6, wherein the supporting zones are formed from a curable compound with less flexibility as compared with the encapsulating compound.

9. The packaged chip of claim 6, wherein the supporting zones are distributed on the backside of the chip with regard to their position and size in such a way that their geometry corresponds to the areal distribution and the extent of the warping of the chip generated under process and operating conditions.

10. The packaged chip of claim 6, wherein the areal form of the supporting zones corresponds to a basic geometrical form.

11. The packaged chip of claim 6, wherein the supporting zones comprise supporting strips.

12. The packaged chip of claim 11, wherein a number of supporting strips are arranged in parallel.

13. The packaged chip of claim 11, wherein at least one supporting strip is arranged transversely in relation to at least one further supporting strip.

14. The packaged chip of claim 6, and further comprising flat and rigid supporting regions connected at least on one side to a surface of the substrate and partially cover the substrate, the supporting regions located between the substrate and the chip.

15. The packaged chip of claim 14, wherein the supporting regions are formed from a lacquer layer

16. The packaged chip of claim 14, wherein the supporting regions are formed in a solder stop mask.

17. The packaged chip of claim 14, wherein the supporting regions are distributed on the substrate with regard to their position and size in such a way that their geometry corresponds to the areal distribution and the extent of the warping of the substrate generated under process and operating conditions.

18. The packaged chip of claim 14, wherein the supporting zones on the backside of the chip and the supporting regions on the substrate are arranged identically.

19. The packaged chip of claim 14, wherein the supporting zones on the backside of the chip and the supporting regions on the substrate are arranged such that they are essentially offset in relation to one another.

20. The packaged chip of claim 14, wherein the supporting zones on the backside of the chip and the supporting regions on the substrate are arranged such that they are essentially rotated by 90° in relation to one another.

21. A substrate for the production of a chip package constructed on this substrate, on which at least one chip is to be mounted, the connection between the substrate and the chip extending virtually completely over one side of the chip, wherein the substrate includes flat and rigid supporting regions that are connected to a surface of the substrate and partially cover the substrate and are arranged at least on one side of the substrate.
